(19) United States
(12) Patent Application Publication
(10) Pub. No.: US 2023/0289486 A1
(43) Pub. Date: Sep. 14, 2023

(54) Systems and Methods for Adaptive Workspace Layout and Usage Optimization

(71) Applicant: Friday PM, Inc., Sunnyvale, CA (US)

(72) Inventors: Juha Christensen, Redwood City, CA (US); Sergii Gorpynich, San Jose, CA (US); Pavlo Khliust, Kyiv (UA); Ivan Grynko, Mykolayiv (UA); Vlad Krylov, Kyiv (UA)

(73) Assignee: Friday PM, Inc., Sunnyvale, CA (US)

(21) Appl. No.: 18/003,094

(22) PCT Filed: Jun. 23, 2021
(86) PCT No.: PCT/US21/38752

§ 371 Date: Dec. 22, 2022

Related U.S. Application Data
(60) Provisional application No. 63/043,729, filed on Jun. 24, 2020.

(51) Int. Cl. G06F 30/10; G06F 30/27

(52) U.S. Cl. CPC G06F 30/10; G06F 30/27

(57) ABSTRACT

Systems and methods for generating adaptive layouts can receive space data relating to a space. The space data includes sensor data from a set of one or more sensors in the space and activity data related to work being performed in the space. The received space data can be analyzed to determine space characteristics data. The space characteristics data includes physical space data related to physical features in the space, work mode data related to types of work performed by users in the space, and user data related to individual users working in the space. Layout data can be generated based on the space characteristic data. The layout data includes positions for several work zones in the space and a target work mode for each work zone of the several work zones. Outputs can be generated based on the generated layout data.

### CROSS REFERENCE TO RELATED APPLICATIONS

This application claims priority to U.S. Provisional Application Ser. No. 63/043,729, entitled “Systems and Methods for Adaptive Workspace Layout and Usage Optimization” to Christensen et al., filed Jun. 24, 2020, the disclosures of which is herein incorporated by reference in its entirety.

### FIELD OF THE INVENTION

This disclosure relates to workspace layout design and more particularly, to digital automated workspace layout, usage and other workspace-related parameters optimization systems.

### BACKGROUND

Traditionally, digital workspace layout systems are used to create different workspace layout concepts and layers. These systems belong to both so-called CAD (computer-aided design) category and generative-design category. Such systems provide assistance to human operators (workspace designers), and some of these systems perform or attempt to perform all of the workspace design functions and steps autonomously. Existing workspace design solutions propose some business drivers for workspace design (layout, floorplan, interior, working models, etc.) based on a limited set of criteria.

### SUMMARY OF THE INVENTION

Systems and methods for generating adaptive layouts in accordance with embodiments of the invention are illustrated. One embodiment includes an adaptive layout generation system, including: a processor, a memory connected to the processor and configured to store an adaptive layout generation application, where the adaptive layout generation application generates design specifications for a work space by directing the processor to: receive workspace data for a first time period relating to the workspace, where the workspace data includes: sensor data from a set of one or more sensors in the workspace; and activity data related to work being performed in the workspace; analyze the received workspace data to determine workspace characteristics data, where the workspace characteristics data includes: physical space data related to physical features in the workspace; work mode data related to types of work performed by users in the workspace; and user data related to individual users working in the workspace; generate layout data based on the workspace characteristic data, where the layout data includes positions for several work zones in the workspace and a target work mode for each work zone of the several work zones; and generate a visual output that provides the design specifications including positions for the several work zones and the target work mode for each work zone in the workspace based on the generated layout data; receive new workspace data for a new time period after the first time period; and generate at least one update for the generated visual output based on the new workspace data.

In a further embodiment, the system includes processing the received space data using a neural network, where the neural network is trained on a training dataset that includes layout data.

In a further embodiment again, a work mode for a work zone is at least one of a dedicated user desk, an unassigned user desk, an activity-based desk used by several users, a sitting desk, and a standing desk.

In a further embodiment still, the adaptive layout generation application further directs the processor to: monitor a metric related to a particular objective, where the objective is at least one of workspace utilization, occupancy, and user satisfaction; and updating the generated visual output when the metric fails to satisfy a criteria.

In yet a further embodiment, the set of sensors includes at least one of a motion sensor, an image sensor, a user flow sensor, a time-of-flight sensor, an infrared (IR) based sensor, an ultrasonic sensor, a thermal sensor, a Carbon dioxide (CO₂) sensor, a vibration sensor, an air quality sensor, a temperature sensor, a humidity sensor, a light sensor, and an audio sensor.

In yet a further embodiment again, the space data further includes feedback data related to feedback from individuals working within the space, environmental data related to environmental conditions in the space.

In yet still a further embodiment, the visual output includes at least one of a visual floor plan, a 3D rendering of a layout, and instructions to modify a layout.

In yet a further embodiment again, the adaptive layout generation application further directs the processor to output control signals to modify an environment of the space.

One embodiment includes a method for adaptive layout generation. The method includes steps for receiving space data relating to a space. The space data includes sensor data from a set of one or more sensors in the space and activity data related to work being performed in the space. The method includes steps for analyzing the received space data to determine space characteristics data. The space characteristics data includes physical space data related to physical features in the space, work mode data related to types of work performed by users in the space, and user data related to individual users working in the space. The method includes steps for generating layout data based on the space characteristic data. The layout data includes positions for several work zones in the space and a target work mode for each work zone of the several work zones. The method includes steps for generating outputs based on the generated layout data.

In a further embodiment, the set of sensors includes at least one of a motion sensor, an image sensor, a time-of-flight sensor, an infrared (IR) based sensor, an ultrasonic sensor, a thermal sensor, a Carbon dioxide (CO₂) sensor, a vibration sensor, an air quality sensor, a temperature sensor, a humidity sensor, a light sensor, and an audio sensor.

In still another embodiment, the space data further includes feedback data related to feedback from individuals working within the space.

In a still further embodiment, the space characteristics data further includes environmental data related to environmental conditions in the space.

In yet another embodiment, the layout data further includes positions and parameters for lighting in the space.

In a yet further embodiment, the layout data further includes predicted metrics for a layout described by the layout data.

In another additional embodiment, the outputs include at least one of a visual floor plan, a 3D rendering of a layout, instructions to modify a layout, and control signals to modify an environment of the space.

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings, which forms a part of this disclosure.

### BRIEF DESCRIPTION OF THE DRAWINGS

The description and claims will be more fully understood with reference to the following figures and data graphs, which are presented as exemplary embodiments of the invention and should not be construed as a complete recitation of the scope of the invention.

FIG. 1 illustrates an example of a space layout in accordance with an embodiment of the invention.

FIG. 2 conceptually illustrates a process for adaptive layout generation in accordance with an embodiment of the invention.

FIG. 3 illustrates an example of an adaptive layout system that generates adaptive layouts in accordance with an embodiment of the invention.

FIG. 4 illustrates an example of an adaptive layout element that generates adaptive layouts in accordance with an embodiment of the invention.

FIG. 5 illustrates an example of an adaptive layout application that generates adaptive layouts in accordance with an embodiment of the invention.

FIG. 6 illustrates an example of a system for generating adaptive layouts using sensor data for a workspace environment in accordance with an embodiment of the invention.

FIG. 7 illustrates an example of a system for using machine learning to generate adaptive layouts based on data from different sensing subsystems in accordance with an embodiment of the invention.

### DETAILED DESCRIPTION

Turning now to the drawings, systems and methods in accordance with a variety of embodiments of the invention can provide automated (without any human intervention), adaptive (continuously learning and improving) workspace layout and usage optimization. One aspect of the present solution is CAFM and IWMS components (CAFM—Computer Aided Facility management, IWMS—integrated workplace management system). While existing CAFM and IWMS solutions rely on human inputs and human decisions to provide for employee to workspace assignment, solutions in accordance with various embodiments of the invention can introduce automated and adaptive employee to workspace assignment.

Systems and methods in accordance with a variety of embodiments of the invention can provide layouts and/or usage optimization that can adapt to changes in user behaviors and environmental conditions. In many embodiments, processes can identify user work modes from sensor data, providing an automated system with the ability to detect work modes and to react accordingly.

Adaptive layout systems in accordance with various embodiments of the invention can be used to generate various layout data, such as (but not limited to) workplace layout, floorplan, interior and exterior geometries and configurations, and different work mode models. In many embodiments, the different types of work modes can include a standing desk, a sitting desk, a dedicated user desk, an unassigned desk such as first come basis or reservation based, an activity-based working area with one or more desks where multiple users can use the particular area such as when a team collaborates on a particular project, hot desking where multiple workers use a single desk during different time periods, hoteling desk that is reservation-based, hoteling desk that is non-reservation based, unassigned desks, among others).

In many embodiments, processes can optimize workspace occupation, workspace users' satisfaction, and/or productivity. Layout design and/or optimization can be based on various elements, such as (but not limited to) anonymized users' data, workspace users' work modes data, work modes occupancy data, environment sensing data, digital employee satisfaction data, digital employee productivity data, employee booking and scheduling requests and/or other parameters.

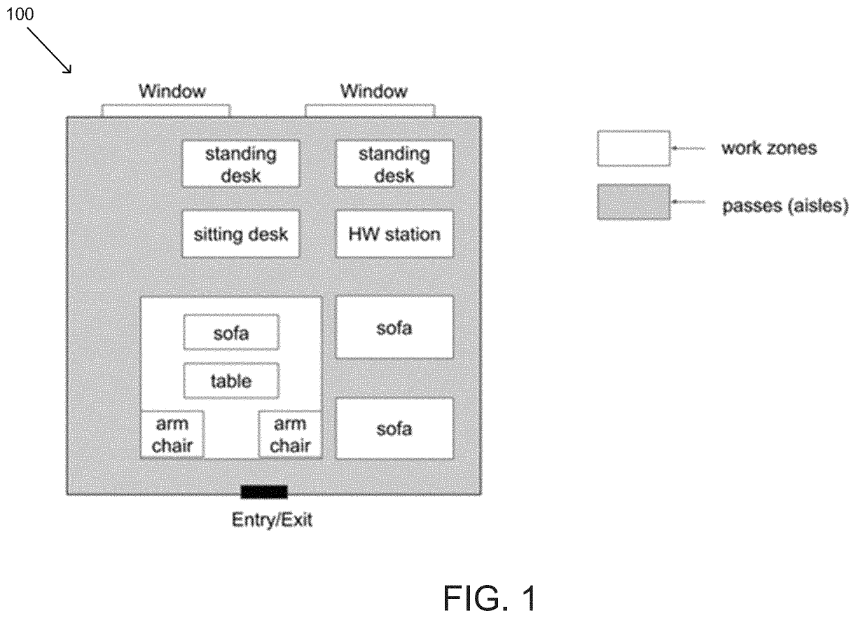

Space layouts in accordance with various embodiments of the invention can be used to describe a layout for a given space. An example of a space layout is illustrated in FIG. 1. In this example, the layout 100 shows work zones (in white) and passes (in grey). Passes can include aisles or pathways between work zones and through the space. Layout 100 also illustrates features of the space, such as windows and an entry/exit. In certain embodiments, layouts can also include furniture, work stations, amenities, lighting, among others. As illustrated in FIG. 1, the layout includes a location of an entry/exit, several different types of working modes, including two standing desks, one sitting desk, and a hot desk station. The layout also includes various office furniture positioned at different locations in the workspace environment.

While specific examples of space layouts have been described above, there are numerous configurations of space layouts, including, but not limited to, those indicating work modes, assignments of users to workspaces/workzones, time scheduling, and/or any other configuration as appropriate to the requirements of a given application.

### Methods for Adaptive Layout Generation

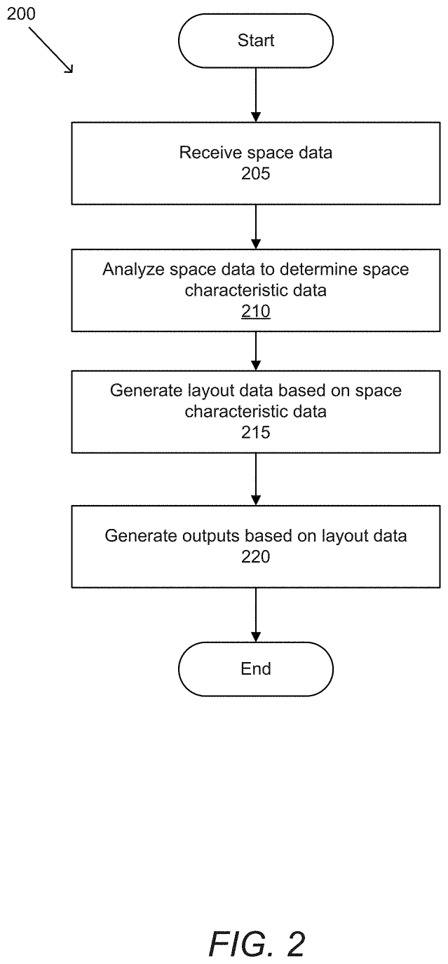

An example of a process for adaptive layout generation in accordance with an embodiment of the invention is illustrated in FIG. 2. Process 200 receives (205) space data. Space data in accordance with a variety of embodiments of the invention can include various types of data related to a given space, such as (but not limited to) sensor data, activity data, feedback data, user data regarding scheduling.

Sensor data in accordance with numerous embodiments of the invention can be captured from one or more of a variety of sensor sub-systems in an area (e.g., a space and/or zone), such as (but not limited to) occupancy sensors, environmental sensors, work zone sensors, work mode sensors, and/user flow sensors. In certain embodiments, sensors in a given sub-system can be shared with other sensor sub-systems. Sensors in accordance with a variety of embodiments of the invention can include (but are not limited to) motion sensors, image sensors (e.g., cameras), video cameras (streaming real-time video cameras), audio sensors (e.g., microphones), temperature sensors, thermal sensors, humidity sensors, light sensors, time-of-flight sensors, infrared (IR) sensors, ultrasonic sensors, Carbon dioxide (CO₂) sensors, vibration sensors, and/or air quality sensors.

Activity data in accordance with various embodiments of the invention can be related to the work that is being performed in an area, such as, but not limited to, computing logs, emails, wireless usage data, chat logs, among various others. Feedback data that indicates feedback from individuals in a space, such as (but not limited to) survey data, booking data, productivity data, among others.

Process 200 analyzes (210) the space data to determine space characteristic data. Space characteristic data in accordance with a number of embodiments of the invention can be determined based on various methodologies, including (but not limited to) computer vision technologies, neural networks, digital signal processing, machine learning, and/or other methods of analysis. In certain embodiments, space characteristic data can be determined for a new space based on space data for one or more existing spaces. In certain embodiments, space characteristic data may include space data (e.g., current temperature, occupancy, among others) as well as related space characteristic data (e.g., average temperatures, expected occupancy, among others). Space characteristic data in accordance with a number of embodiments of the invention that can be determined from the sensor data can include (but is not limited to) physical space data (e.g., data related to physical features in a space or zone), environmental data (e.g., data related to environmental conditions in a space or zone), work mode data (e.g., data related to the type of work performed in a space or zone), and/or user data (e.g., data related to individuals to occupy the space).

Physical space data in accordance with certain embodiments of the invention can include information about workspace boundaries, including walls and windows as well as entries, exits to and from the workspace. In several embodiments, physical space data can define workspace geometries based on known visual processing techniques. Physical space data in accordance with some embodiments of the invention can also include information about physical features within a space, whether currently installed or available to be installed, such as, but not limited to, furniture, space sections, amenities, among others. In a number of embodiments, physical space data can describe the capability of the workspace to address the needs of the space users (to support space user's work modes).

Environmental data in accordance with numerous embodiments of the invention can include information about the environment or conditions of a space, such as lighting levels, temperature, humidity, CO₂ levels, noise and vibration in the different sections of the workspace.

Work mode data in accordance with many embodiments of the invention can include information about how users operate in a space, such as (but not limited to) work zone occupancy (e.g., frequency, group size, time of day, etc.), the ways space users move within the space, as well as the actual work modes in which workspace users operate. Work modes in accordance with a variety of embodiments of the invention can be determined based on the observed ways workspace users work and collaborate with each other. In various embodiments, activity information (e.g., emails, computer logs, among others) can be used in combination with other work mode data and/or user data to determine a work mode for users in a given space. In certain embodiments, work mode data can include work mode preferences, which can be provided by the space users (e.g., via digital customer surveys, from digital work zone allocations (or bookings) requests, among others).

In certain embodiments, work mode data can be determined using one or more machine learning models, such as (but not limited to) artificial neural networks, decision trees, recurrent models, regression models, and/or convolutional models. Models in accordance with many embodiments of the invention can be trained on sensor data (e.g., motion data, video data, etc.) that is annotated with work modes.

User data in accordance with various embodiments of the invention can include information about users and/or their interactions within a space. In numerous embodiments, user data can be used in conjunction with work mode data to identify work mode data based on the individual users, such as (but not limited to) which of the work zones are dedicated and which are shared, how different people work together. In a number of embodiments, user data can be anonymized to protect the identity of individual users, while still maintaining the individuality of different users in the analysis of a space.

Process 200 generates (215) layout data from the space characteristic data. In several embodiments, layout data can include (but is not limited to) positions and parameters for work zones, aisles, as well as various elements within a space such as (but not limited to) fixtures, furniture, lighting, noise reduction structures, HVAC systems, power and connectivity wiring for the workspace, and/or other work equipment (e.g., mobile conferencing stations, coffee stations, clothing wardrobes, private lockers, etc.). Parameters can include (but are not limited to) brightness, target temperatures (or ranges), dimensions, colors, among others. In some embodiments, layout data can include metrics for expected space characteristics, expected cost, satisfaction scores, among others.

Layout data in accordance with various embodiments of the invention can be generated for a re-design of an existing space and/or as plans for a new space. Layout data in accordance with a number of embodiments of the invention can include working modes, types, sizes, and locations of the work zones within the space as well as passes from the entrance/exit of the workspace to all work zones within the space as well as passes between the work zones within the space.

Generating layout data in accordance with several embodiments of the invention can be based on optimizing a set of one or more objectives and/or a set of one or more constraints. Objectives in accordance with some embodiments of the invention can include (but are not limited to) cost, workspace utilization, occupancy, user satisfaction, and/or productivity. Examples of optimizations include optimizing the number of workspace users allocated to a workspace, maximizing utilization rates, optimizing for a weighted balance of multiple objectives, among others. Examples of constraints in accordance with a number of embodiments of the invention can include (but are not limited to) a minimum number of users served, a maximum budget, a desk space requirement, aisle widths, accessibility, power/network outlet proximity, etc.

In a number of embodiments, generating layout data comprises generating a database of required work zones that can optimally support prevalent work modes (e.g., as identified in the space characteristic data) and/or occupancy. Design to support work modes in accordance with a number of embodiments of the invention can be based on activity-based workspace design principles, which provide proven efficiency. In certain embodiments, work zones (e.g., size, type, design, number, among others) can be designated for a layout based on activity data and/or feedback data from users of a space.

In many embodiments, generating layout data comprises analyzing users through a space and/or environmental data to shape a passes network between zones of a space. Shaping passes networks in accordance with various embodiments of the invention can be performed to minimize user paths through a space, to increase points of interaction, among others. Generating layout data in accordance with various embodiments of the invention can include providing metadata about a generated layout and/or users in a layout, such as (but not limited to) users/teams profiles, benchmarks with respective industry and/or internal data, suggestions for best matching workplace design for given profiles, and/or simulated metrics (e.g., to forecast occupancy, utilization, vacancy, satisfaction score, reduced costs, spending, payback period, among others) as a function of workspace design.

Process 200 generates (220) outputs based on the generated layout data. Outputs in accordance with certain embodiments of the invention can include visual floor plans, 3D visual floorplans, renderings, reports, and/or charts. In numerous embodiments, processes can provide notifications as output, such as (but not limited to) alarms, instructions to modify a zone and/or space, recommended allocations of work zones to users, among others. Processes in accordance with several embodiments of the invention can generate control signals to modify parameters of elements (e.g., lights, temperature, music volume, among others) within a space.

Processes in accordance with numerous embodiments of the invention can employ machine learning techniques to generate layout data, such that adaptive layout systems can continuously learn, without human intervention, based on previously designed workspaces and previously collected data within the current workspace. Processes in accordance with several embodiments of the invention can store information about the mapping of the collected data to the workspace design solution which is assessed to be optimal. Processes in accordance with a variety of embodiments of the invention can use transfer learning and/or federated learning principles to use previously collected information (mapping) to provide for the optimal design of the next workspaces.

While specific processes for adaptive layout generation are described above, any of a variety of processes can be utilized to generate adaptive layouts as appropriate to the requirements of specific applications. In certain embodiments, steps may be executed or performed in any order or sequence not limited to the order and sequence shown and described. In a number of embodiments, some of the above steps may be executed or performed substantially simultaneously where appropriate or in parallel to reduce latency and processing times. In some embodiments, one or more of the above steps may be omitted.

In some embodiments, processes for adaptive layout generation can be performed iteratively, periodically, and/or continuously. Processes in accordance with many embodiments of the invention can perform the data gathering and analysis steps as new data is received. In certain embodiments, processes can determine when a current layout (or parameters of that layout) no longer meets certain criteria or thresholds, and can evaluate layouts and/or space characteristics to determine whether to provide new layout recommendations and/or instructions to modify parameters or positions of elements of the layout design. In a variety of embodiments, when processes assess that the workspace layout or/and other parameters becomes different from the actually implemented layout and/or expected parameters, the system indicates this to users of the system, providing them with the actionable insights on system outputs and controlled parameters. In various embodiments, processes can continuously track work mode(s) of the individual workspace users or a team and can recommend (e.g., in real-time and/or as a summary recommendation over time period) specific work zones which might be optimal for implementation of the current work or prevalent work modes, as well as locations of such work zones in the workspace.

### Systems for Adaptive Layout Generation

### Adaptive Layout System

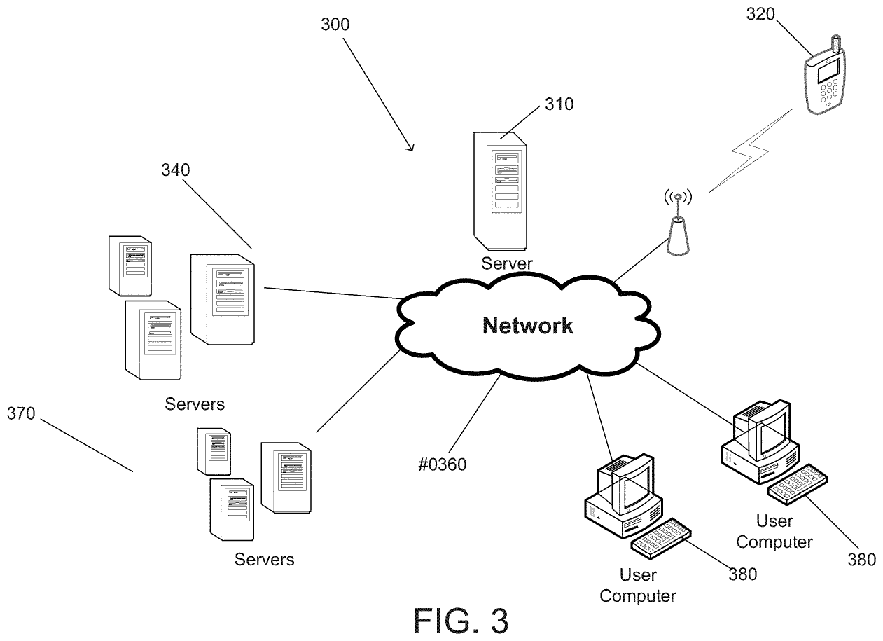

An example of an adaptive layout system that generates adaptive layouts in accordance with some embodiments of the invention is illustrated in FIG. 3. Network 300 includes a communications network 360. The communications network 360 is a network such as the Internet that allows devices connected to the network 360 to communicate with other connected devices. Server systems 310, 340, and 370 are connected to the network 360. Each of the server systems 310, 340, and 370 is a group of one or more servers communicatively connected to one another via internal networks that execute processes that provide cloud services to users over the network 360. One skilled in the art will recognize that an adaptive layout system may exclude certain components and/or include other components that are omitted for brevity without departing from this invention.

For purposes of this discussion, cloud services are one or more applications that are executed by one or more server systems to provide data and/or executable applications to devices over a network. The server systems 310, 340, and 370 are shown each having three servers in the internal network. However, the server systems 310, 340 and 370 may include any number of servers and any additional number of server systems may be connected to the network 360 to provide cloud services. In accordance with various embodiments of this invention, an adaptive layout system that can generate adaptive layouts in accordance with an embodiment of the invention may be provided by a process being executed on a single server system and/or a group of server systems communicating over network 360.

Users may use personal devices 380 and 320 that connect to the network 360 to perform processes that generate adaptive layouts in accordance with various embodiments of the invention. In the shown embodiment, the personal devices 380 are shown as desktop computers that are connected via a conventional “wired” connection to the network 360. However, the personal device 380 may be a desktop computer, a laptop computer, Internet of Things (IoT) device, a smart television, an entertainment gaming console, imaging system, microphone, sensor system, or any other device that connects to the network 360 via a “wired” connection. The mobile device 320 connects to network 360 using a wireless connection. A wireless connection is a connection that uses Radio Frequency (RF) signals, Infrared signals, or any other form of wireless signaling to connect to the network 360. In FIG. 3, the mobile device 320 is a mobile telephone. However, mobile device 320 may be a mobile phone, Personal Digital Assistant (PDA), a tablet, a smartphone, or any other type of device that connects to network 360 via wireless connection without departing from this invention.

As can readily be appreciated the specific computing system used to generate adaptive layouts is largely dependent upon the requirements of a given application and should not be considered as limited to any specific computing system(s) implementation.

### Adaptive Layout Element

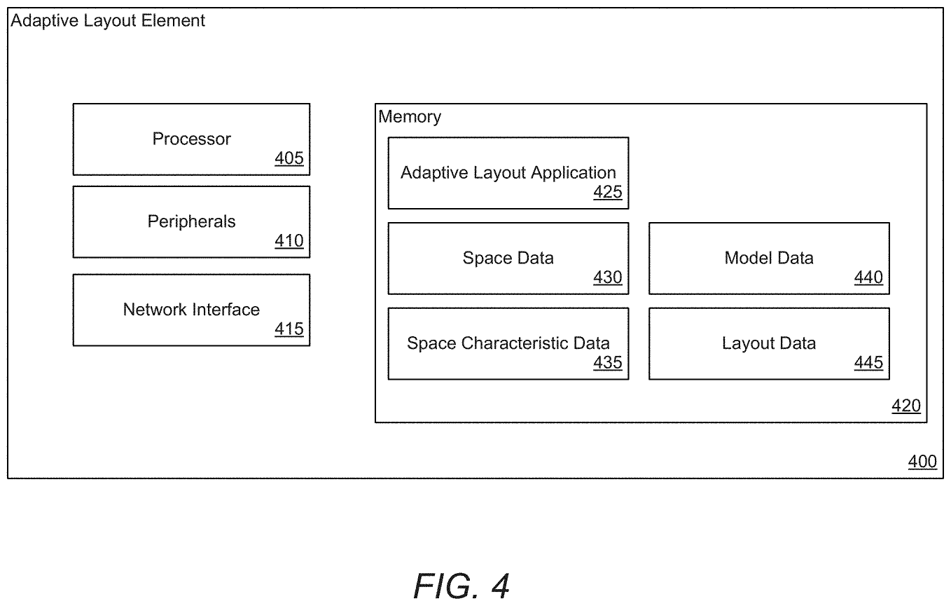

An example of an adaptive layout element that executes instructions to perform processes that generate adaptive layouts in accordance with various embodiments of the invention is illustrated in FIG. 4. Adaptive layout elements in accordance with many embodiments of the invention can include (but are not limited to) one or more of mobile devices, cameras, and/or computers. Adaptive layout element 400 includes processor 405, peripherals 410, network interface 415, and memory 420. One skilled in the art will recognize that an adaptive layout element may exclude certain components and/or include other components that are omitted for brevity without departing from this invention.

The processor 405 can include (but is not limited to) a processor, microprocessor, controller, or a combination of processors, microprocessor, and/or controllers that performs instructions stored in the memory 420 to manipulate data stored in the memory. Processor instructions can configure the processor 405 to perform processes in accordance with certain embodiments of the invention.

Peripherals 410 can include any of a variety of components (or modules for communicating with such components) for capturing data, such as (but not limited to) video cameras, image cameras, microphones, displays, and/or sensors. In a variety of embodiments, peripherals can be used to gather inputs and/or provide outputs. Sensors in accordance with a variety of embodiments of the invention can be used to measure various characteristics, such as (but not limited to) lighting levels, temperature, humidity, CO2 levels, noise, and/or vibration.

Adaptive layout element 400 can utilize network interface 415 to transmit and receive data over a network based upon the instructions performed by processor 405. Peripherals and/or network interfaces in accordance with many embodiments of the invention can be used to gather inputs that can be used to generate adaptive layouts and/or to display generated outputs.

Memory 420 includes an adaptive layout application 425, space data 430, space characteristic data 435, and model data 440. Adaptive layout applications in accordance with several embodiments of the invention can be used to generate adaptive layouts.

Space data in accordance with many embodiments of the invention can include various types of data related to a given space, such as (but not limited to) sensor data, activity data, and/or feedback data. In various embodiments, space characteristic data can be determined based on various methodologies, including (but not limited to) computer vision technologies, neural networks, digital signal processing, machine learning, and/or other methods of analysis. Space characteristic data in accordance with a number of embodiments of the invention can include (but is not limited to) physical space data, environmental data, work mode data, and/or user data.

In several embodiments, model data can store various parameters and/or weights for models used for analyzing space data and/or generating layout data. Model data in accordance with many embodiments of the invention can be updated through training on multimedia data captured on an adaptive layout element or can be trained remotely and updated at an adaptive layout element. Models in accordance with several embodiments of the invention can include (but are not limited to) artificial neural networks, decision trees, recurrent models, regression models, and/or convolutional models.

Layout data in accordance with some embodiments of the invention can include positions and parameters for work zones, aisles, as well as various elements within a space such as (but not limited to) fixtures, furniture, lighting, noise reduction structures, HVAC systems, power and connectivity wiring for the workspace, and/or other work equipment (e.g., mobile conferencing stations, coffee stations, clothing wardrobes, private lockers, etc.). In some embodiments, layout data can include metrics for expected space characteristics, expected cost, satisfaction scores, etc.

Although a specific example of an adaptive layout element 400 is illustrated in FIG. 4, any of a variety of adaptive layout elements can be utilized to perform processes for adaptive layout generation similar to those described herein as appropriate to the requirements of specific applications in accordance with embodiments of the invention.

### Adaptive Layout Application

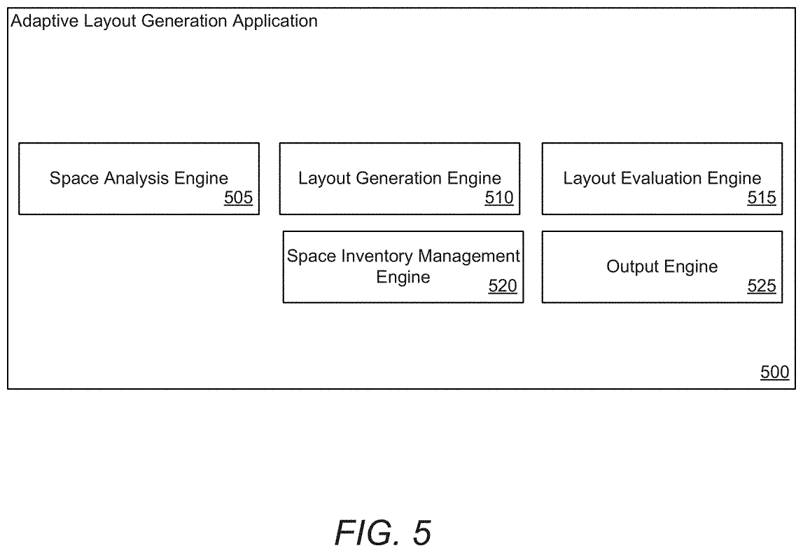

An example of an adaptive layout application for adaptive layout generation in accordance with an embodiment of the invention is illustrated in FIG. 5. Adaptive layout application 500 includes space analysis engine 505, layout generation engine 510, layout evaluation engine 515, space inventory management engine 520, and output engine 525. One skilled in the art will recognize that an adaptive layout application may exclude certain components and/or include other components that are omitted for brevity without departing from this invention.

Space analysis engines in accordance with many embodiments of the invention can analyze space data to determine space characteristics. In numerous embodiments, space analysis engines can gather data from various sources (e.g., sensors, surveys, booking systems, system logs, among others) to determine a variety of characteristics of a space and/or of users within the space. Space characteristics can include boundaries, user path data, work modes, occupancy, furniture positions, lighting parameters and/or positions, among others.

In many embodiments, layout generation engines can generate layouts based on space characteristics. Layouts in accordance with some embodiments of the invention can optimize for different objectives and/or based on various constraints. In a number of embodiments, layout generation engines can include one or more machine learning models to generate layout data.

Layout evaluation engines in accordance with several embodiments of the invention can evaluate generated layout data. In a number of embodiments, existing layouts can be evaluated to determine whether changes should be made (e.g., when a score for a layout does not exceed a given threshold). Layout evaluation engines in accordance with various embodiments of the invention can predict or estimate the performance of a layout across various metrics, such as user satisfaction, occupancy, among others. In several embodiments, layout evaluation engines can include machine learning models to evaluate layout data.

In various embodiments, space inventory management engines can be used to manage users and layouts. Space inventory management engines in accordance with certain embodiments of the invention can assign or recommend zones to particular users and/or teams, based on their histories and/or preferred work modes. In many embodiments, space inventory management systems can manage booking for different work zones. Space inventory management engines in accordance with some embodiments of the invention can manage the availability of different work zones and/or amenities.

Output engines in accordance with several embodiments of the invention can provide a variety of outputs to a user, including (but not limited to) floor plans, renderings, notifications, alerts, charts, reports, and/or control signals.

Although a specific example of an adaptive layout application 500 is illustrated in FIG. 5, any of a variety of adaptive layout applications can be utilized (e.g., with fewer or additional components) to perform processes for adaptive layout generation similar to those described herein as appropriate to the requirements of specific applications in accordance with embodiments of the invention.

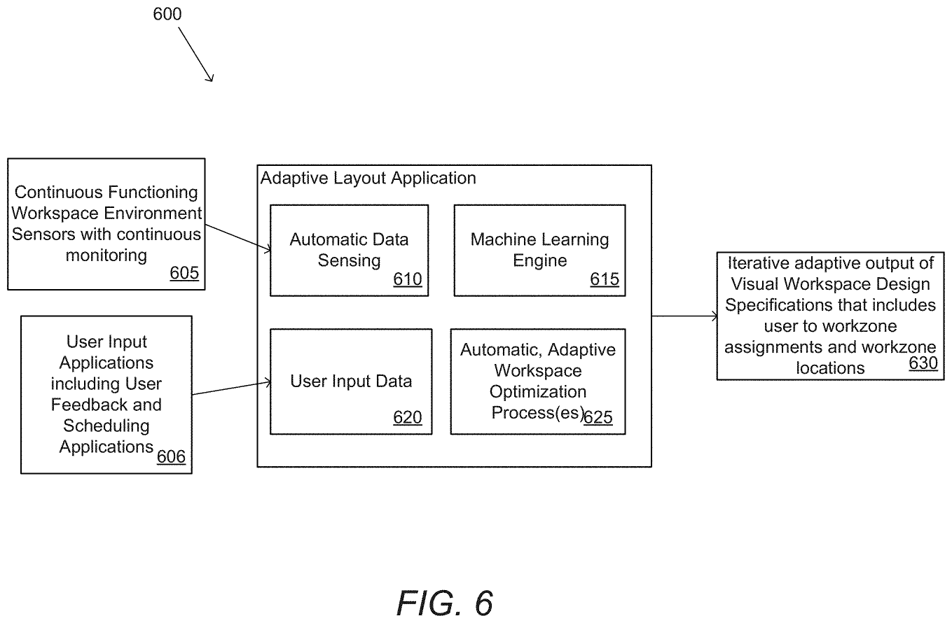

In many embodiments, a system for adaptive layout generation can continuously monitor a workspace environment using several different types of sensors and generate and/or update an implemented layout design, including work zones, passes, worker modes, among various other floor plan design and feature specifications based on various optimization processes that can be applied to changing work habits and needs of a workplace environment. FIG. 6 illustrates a system for continuous monitoring and updating a workspace environment in accordance with an embodiment of the invention. The system 600 can include a variety of different workspace sensors 605 for monitoring a workspace and providing sensor data. The sensors can include monitoring user path data, work modes, occupancy, furniture positions, lighting parameters and/or positions, among others. The system can also receive user input data regarding feedback related to the workspace environment, scheduling and booking requests, among other applications. The adaptive layout application can continuously sense and process the various types data, using automatic data sensing module 610, and the user input data module 620. In many embodiments, occupancy sensors, work zone sensors, work mode sensors, and user flow sensors can be implemented using sensor data in combination with deep learning and artificial neural networks to ascertain the different types of information, among other techniques.

In many embodiments, the machine learning techniques can be used to process the data sensed from the workspace environment sensors, user input data from the user applications. In several embodiments, certain continuous workspace optimization processes can continuously monitor and process the sensed data and/or user input data. The system can generate 630 a visual output that can be periodically updated/adapted. The visual output can include layout data with workspace design specifications which can include work zone locations within a workspace, user passes thru work zones, user to work zone assignments, work mode assignments (e.g., standing desk, hot desk, unassigned desk, reserved desk, among others) for work zones, and/or other design specifications and floorplan modifications. In many embodiments, the output can be a visual design of a workspace that includes working modes, types, sizes, location of the work zones within the space, passes from/to the entrance(s) and exit(s) of the workspace to the work zones within the space, and passes between the work zones in the space. In many embodiments, an output can be periodically updated or new information can be obtained (e.g., analysis of activity data indicates that several users should be working together on a project and thus their seats should be rearranged), whereby the workspace can be reconfigured/adapted accordingly (e.g., desks moved, furniture rearranged, users/employees reassigned to different locations among others), and thus new sensor data for the new configuration can be used by various optimization processes related to the workspace to monitor how the newly adapted configuration is performing relative to various different metrics (e.g., productivity, user satisfaction, among others). For example, if the system detects user flow traffic through a particular pass within the work environment that is overly congested, the system can reconfigure the layout to reduce the traffic by specifying modified and/or new passes, rearranging work zones, including furniture and employee desks, among other reconfigurations in order to provide a better working environment. Although FIG. 6 illustrates a particular system architecture for continuous monitoring and updating a workspace environment, any of a variety of system architectures with different types of processes can be utilized as appropriate to the requirements of specific applications in accordance with many embodiments of the invention.

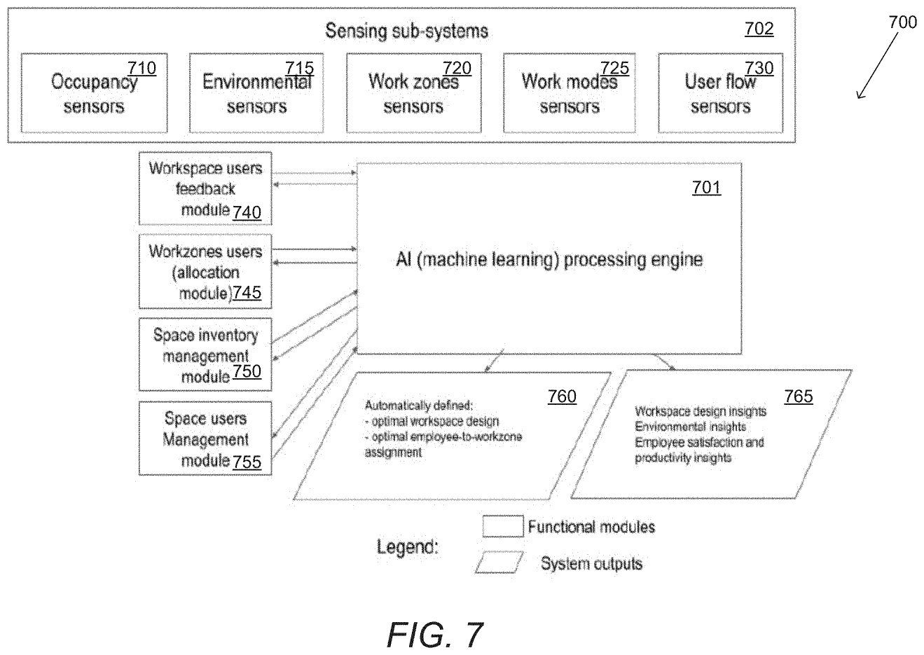

Many different types of data from different sensing subsystems can be utilized with machine learning techniques to generate workspace designs and user/employee to workzone assignments. A system for generating a workspace design and user-to workzone assignments in accordance with an embodiment of the invention is illustrated in FIG. 7. The system 700 includes sensing sub-system 702, including occupancy sensors 705, environmental sensors 710, work zone sensors 720, work mode sensors 725, and user flow sensors 730. The system 700 can also include workspace user feedback module 740, workzone users (allocation module), space inventory management module 750, and space user management module.

Different types of data from the different sensing sub-systems 702 can be processed using machine learning processing engine 701. Data from the different modules 740, 745, 750, and 755 can also be processed using the machine learning processing engine 701. In many embodiments, the output can include a visual floorplan output 760 with workspace design specification and user-to-workzone assignments. In several embodiments, the output can include workspace design metrics, environmental metrics, user satisfaction metrics, productivity metrics, among various other metrics and/or insights regarding the workspace environment. Although FIG. 7 illustrates a particular system architecture with a set of different types of sensing subsystems processed with machine learning, any of a variety of types of data and sensors can be utilized using machine learning, linear programming, and various other optimization techniques as appropriate to the requirements of specific applications in accordance with many embodiments of the invention.

Although specific methods of adaptive layout are discussed above, many different methods of adaptive layout can be implemented in accordance with many different embodiments of the invention. It is therefore to be understood that the present invention may be practiced in ways other than specifically described, without departing from the scope and spirit of the present invention. Thus, embodiments of the present invention should be considered in all respects as illustrative and not restrictive. Accordingly, the scope of the invention should be determined not by the embodiments illustrated, but by the appended claims and their equivalents.

What is claimed is:

1. An adaptive layout generation system, comprising:
a processor;
a memory connected to the processor and configured to store an adaptive layout generation application;
wherein the adaptive layout generation application generates design specifications for a workspace by directing the processor to:
receive workspace data for a first time period relating to the workspace, wherein the workspace data comprises:
sensor data from a set of one or more sensors in the workspace; and
activity data related to work being performed in the workspace;
analyze the received workspace data to determine workspace characteristics data, wherein the workspace characteristics data comprises:
physical space data related to physical features in the workspace;
work mode data related to types of work performed by users in the workspace; and
user data related to individual users working in the workspace;
generate layout data based on the workspace characteristic data, wherein the layout data comprises positions for a plurality of work zones in the workspace and a target work mode for each work zone of the plurality of work zones;
generate a visual output that provides the design specifications including positions for the plurality of work zones and the target work mode for each work zone in the workspace based on the generated layout data;
receive new workspace data for a new time period after the first time period; and
generate at least one update for the generated visual output based on the new workspace data.

2. The system of claim 1, further comprising processing the received space data using a neural network, wherein the neural network is trained on a training dataset that includes layout data.

3. The system of claim 1, wherein a work mode for a work zone is at least one of a a dedicated user desk, an unassigned user desk, an activity-based desk used by a plurality of users, a sitting desk, and a standing desk.

4. The system of claim 1, wherein updating the generated visual output further comprises:
monitoring a metric related to a particular objective, wherein the objective is at least one of workspace utilization, occupancy, and user satisfaction; and
updating the generated visual output when the metric fails to satisfy a criteria.

5. The system of claim 1, wherein the set of sensors comprises at least one of a motion sensor, an image sensor, a user flow sensor, a time-of-flight sensor, an infrared (IR) based sensor, an ultrasonic sensor, a thermal sensor, a Carbon dioxide (CO₂) sensor, a vibration sensor, an air quality sensor, a temperature sensor, a humidity sensor, a light sensor, and an audio sensor.

6. The system of claim 1, wherein the space data further comprises feedback data related to feedback from individuals working within the space, environmental data related to environmental conditions in the space.

7. The system of claim 1, wherein the visual output comprises at least one of a visual floor plan, a 3D rendering of a layout, and instructions to modify a layout.

8. The system of claim 1, wherein the adaptive layout generation application further directs the processor to output control signals to modify an environment of the space.

9. The system of claim 1, wherein generating layout data based on the space characteristic data comprises performing at least one optimization process with respect to an objective, wherein the objective is at least one of cost, workspace utilization, occupancy, user satisfaction, and productivity.

10. A method for adaptive layout generation, the method comprising:
receiving space data relating to a workspace, wherein the workspace data comprises:
sensor data from a set of one or more sensors in the workspace; and
activity data related to work being performed in the workspace;
analyzing the received space data to determine space characteristics data, wherein the space characteristics data comprises:
physical space data related to physical features in the workspace;
work mode data related to types of work performed by users in the workspace; and
user data related to individual users working in the workspace;
generating layout data based on the space characteristic data, wherein the layout data comprises positions for a plurality of work zones in the workspace and a target work mode for each work zone of the plurality of work zones; and
generating visual outputs based on the generated layout data.

11. The method of claim 10, wherein the space data is associated with a first time period, wherein the method further comprises:
receiving new space data for a time period after the first time period;
updating the generated visual outputs based on the new space data.

12. The method of claim 10, further comprising processing the received space data using a neural network, wherein the neural network is trained on a training dataset that includes layout data.

13. The method of claim 10, wherein a work mode for a work zone is at least one of a dedicated user desk, an unassigned user desk, an activity-based desk used by a plurality of users, a sitting desk, and a standing desk.

14. The method of claim 11, wherein updating the generated visual output further comprises:
monitoring a metric related to a particular objective, wherein the objective is at least one of workspace utilization, occupancy, and user satisfaction; and
updating the generated visual outputs when the metric fails to satisfy a criteria.

15. The method of claim 10, wherein the set of sensors comprises at least one of a motion sensor, an image sensor, a user flow sensor, a time-of-flight sensor, an infrared (IR) based sensor, an ultrasonic sensor, a thermal sensor, a Carbon dioxide (CO₂) sensor, a vibration sensor, an air quality sensor, a temperature sensor, a humidity sensor, a light sensor, and an audio sensor.

16. The method of claim 10, wherein the space data further comprises feedback data related to feedback from individuals working within the workspace, environmental data related to environmental conditions in the workspace.

17. The method of claim 10, wherein the visual output comprises at least one of a visual floor plan, a 3D rendering of a layout, and instructions to modify a layout.

18. The method of claim 10, further comprising outputting control signals to modify an environment of the workspace.

19. The method of claim 10, wherein generating layout data based on the space characteristic data comprises performing at least one optimization process with respect to an objective, wherein the objective is at least one of cost, workspace utilization, occupancy, user satisfaction, and productivity.
